(19) United States
(12) Patent Application Publication
(10) Pub. No.: US 2025/0017114 A1
(43) Pub. Date: Jan. 9, 2025

(54) MULTILAYER CERAMIC ELECTRONIC COMPONENT AND ASSEMBLY

(71) Applicant: NGK INSULATORS, LTD., Nagoya-shi (JP)

(72) Inventors: Akifumi MORISHITA, Komaki-shi (JP); Tomohiko HIBINO, Inazawa-shi (JP)

(21) Appl. No.: 18/890,823

(22) Filed: Sep. 20, 2024

Related U.S. Application Data
(63) Continuation of application No. PCT/JP2022/016553, filed on Mar. 31, 2022.

(51) Int. Cl. H10N 30/87; H10N 30/20; H10N 30/50; H10N 30/853

(52) U.S. Cl. CPC H10N 30/871; H10N 30/206; H10N 30/50; H10N 30/853; H10N 30/872

(57) ABSTRACT

A first side surface electrode connects a first external electrode layer to the second internal electrode layer on the first side surface, and is separated from the first internal electrode layer. A second side surface electrode connects the second external electrode layer to the first internal electrode layer on the second side surface, and is separated from the second internal electrode layer. In a two-dimensional layout, all of the following regions overlap each other in a portion higher than or equal to 75% of a region in which the piezoelectric ceramic part is disposed: a region in which the first external electrode layer and the first internal electrode layer overlap each other; a region in which the first internal electrode layer and the second internal electrode layer overlap each other; and a region in which the second external electrode layer and the second internal electrode layer overlap each other.

### CROSS-REFERENCE TO RELATED APPLICATION

This application is a continuation application of PCT/JP2022/016553, filed on Mar. 31, 2022, the content of which is hereby incorporated by reference into this application.

### BACKGROUND

### Technical Field

The present disclosure relates to a multilayer ceramic electronic component and an assembly.

### Description of the Background Art

Japanese Patent Application Laid-Open No. 2017-183542 discloses a piezoelectric element favorably used as an actuator. The piezoelectric element includes a piezoelectric body, a first electrode, and a second electrode. The piezoelectric body is formed into a rectangular parallelepiped that extends in a longitudinal direction. The piezoelectric body has a pair of end surfaces, a pair of first side surfaces, and a pair of second side surfaces. The pair of end surfaces, the pair of first side surfaces, and the pair of second side surfaces are surfaces of the piezoelectric body. The end surfaces are vertical in the longitudinal direction, and face each other. The first side surfaces extend parallel to the longitudinal direction, and face each other. The second side surfaces extend parallel to the longitudinal direction, and face each other. The pair of second side surfaces is orthogonal to the pair of first side surfaces. In the piezoelectric element, a first inner electrode and a first outer electrode function as a first electrode for applying an electrical field to the piezoelectric body, and a second inner electrode and a second outer electrode function as a second electrode for applying an electrical field to the piezoelectric body. In the piezoelectric body, a region sandwiched between a second electrode portion and the first inner electrode, a region sandwiched between the first inner electrode and the second inner electrode, and a region sandwiched between the second inner electrode and a third electrode portion are active regions that are displaced in response to the applied electrical fields.

The piezoelectric body disclosed in Japanese Patent Application Laid-Open No. 2017-183542 lacks the active regions at both ends in the longitudinal direction as a displacement direction of the actuator, across dimensions that are non-negligible in view of a piezoelectric displacement. Consequently, the amount of displacement that can be generated by the actuator (a multilayer ceramic electronic component) becomes small. The more the dimensions of the piezoelectric body are increased in the displacement direction, the more the amount of displacement increases; however, the dimensions normally have constraints.

### SUMMARY

A multilayer ceramic electronic component according to the present disclosure includes a piezoelectric ceramic part. The piezoelectric ceramic part includes: a first main surface and a second main surface that are opposite to each other in a thickness direction; a first end surface and a second end surface that are opposite to each other in a first direction different from the thickness direction; a first side surface and a second side surface that are opposite to each other in a second direction different from the thickness direction and the first direction; and a first dimension in the first direction and a second dimension in the second direction, the first dimension being larger than the second dimension. The multilayer ceramic electronic component further includes: a first external electrode layer disposed on the first main surface; a second external electrode layer disposed on the second main surface; a first internal electrode layer disposed between the first external electrode layer and the second external electrode layer in the piezoelectric ceramic part; a second internal electrode layer disposed between the second external electrode layer and the first internal electrode layer in the piezoelectric ceramic part; a first side surface electrode that connects the first external electrode layer to the second internal electrode layer on the first side surface, the first side surface electrode being separated from the first internal electrode layer; and a second side surface electrode that connects the second external electrode layer to the first internal electrode layer on the second side surface, the second side surface electrode being separated from the second internal electrode layer. In a two-dimensional layout including the first direction and the second direction, all of the following regions overlap each other in a portion higher than or equal to 75% of a region in which the piezoelectric ceramic part is disposed: a region in which the first external electrode layer and the first internal electrode layer overlap each other; a region in which the first internal electrode layer and the second internal electrode layer overlap each other; and a region in which the second external electrode layer and the second internal electrode layer overlap each other.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a side view schematically illustrating a structure of an assembly according to Embodiment 1.

FIG. 2 is a top view schematically illustrating a structure of a multilayer ceramic electronic component according to Embodiment 1.

FIG. 3 is a bottom view schematically illustrating the structure of the multilayer ceramic electronic component according to Embodiment 1.

FIG. 4 is a left-side view schematically illustrating the structure of the multilayer ceramic electronic component according to Embodiment 1.

FIG. 5 is a right-side view schematically illustrating the structure of the multilayer ceramic electronic component according to Embodiment 1.

FIG. 6 is a top view schematically illustrating a structure of a multilayer ceramic electronic component of a comparative example.

FIG. 7 is a bottom view schematically illustrating the structure of the multilayer ceramic electronic component of the comparative example.

FIG. 8 is a left-side view schematically illustrating the structure of the multilayer ceramic electronic component of the comparative example.

FIG. 9 is a right-side view schematically illustrating the structure of the multilayer ceramic electronic component of the comparative example.

FIG. 10 is a graph illustrating an example simulation result on a relationship between a voltage and the amount of displacement in Example of Embodiment 1 and the comparative example.

FIG. 11 is a graph illustrating an example simulation result on a relationship between an active area percentage and the amount of displacement.

FIG. 12 is a top view schematically illustrating a structure of a multilayer ceramic electronic component according to Embodiment 2.

FIG. 13 is a top view schematically illustrating a structure of a multilayer ceramic electronic component according to a first modification of Embodiment 2.

FIG. 14 is a top view schematically illustrating a structure of a multilayer ceramic electronic component according to a second modification of Embodiment 2.

FIG. 15 is a top view schematically illustrating a structure of a multilayer ceramic electronic component according to Embodiment 3.

FIG. 16 is a graph illustrating a distribution of an inactive length in the multilayer ceramic electronic component of FIG. 15.

FIG. 17 is a graph illustrating a distribution of an inactive length in the multilayer ceramic electronic component of FIG. 2.

FIG. 18 is a top view schematically illustrating a structure of a multilayer ceramic electronic component according to a first modification of Embodiment 3.

FIG. 19 is a graph illustrating a distribution of an inactive length in the multilayer ceramic electronic component of FIG. 18.

FIG. 20 is a top view schematically illustrating a structure of a multilayer ceramic electronic component according to a second modification of Embodiment 3.

FIG. 21 is a graph illustrating a distribution of an inactive length in the multilayer ceramic electronic component of FIG. 20.

FIG. 22 is a contour map illustrating an example simulation result on a stress distribution near an inactive region in the multilayer ceramic electronic component of FIG. 2 under a piezoelectric displacement.

FIG. 23 is a vector diagram corresponding to FIG. 22.

FIG. 24 is a contour map illustrating an example simulation result on a stress distribution near an inactive region in the multilayer ceramic electronic component of FIG. 15 under a piezoelectric displacement.

FIG. 25 is a vector diagram corresponding to FIG. 24.

### DESCRIPTION OF THE PREFERRED EMBODIMENTS

Embodiments according to the present disclosure will be hereafter described based on the drawings. Some of the drawings use an XYZ rectangular coordinate system including directions X, Y, and Z to facilitate the understanding of directional relationships between these drawings. The same reference numerals are assigned to the same or equivalent portions in the drawings, and the description is not repeated. The terms “up”, “down”, “left”, and “right” are sometimes used in the Description in conjunction with the drawings. These terms are intended for facilitating the understanding of directional relationships between a plurality of drawings, and do not mean that an attitude of a structure illustrated in the drawings has to be oriented in a particular direction.

### Embodiment 1

### [Structure of Assembly]

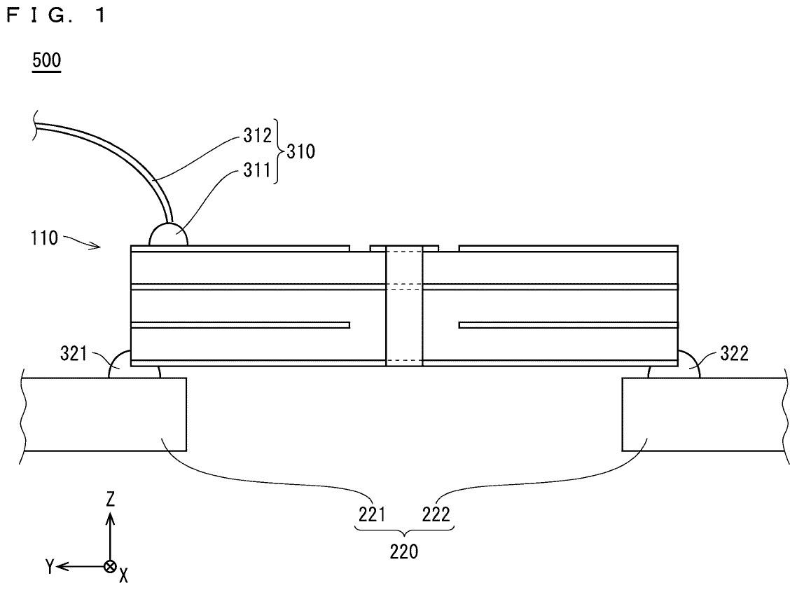

FIG. 1 is a side view schematically illustrating a structure of an assembly 500 according to Embodiment 1. The assembly 500 includes a multilayer ceramic electronic component 110, and a mounted component 220 on which the multilayer ceramic electronic component 110 is mounted. The multilayer ceramic electronic component 110 is a piezoelectric actuator for generating a displacement in a length direction Y (a first direction) as a displacement direction.

The mounted component 220 includes a first supporter 221 and a second supporter 222 that support the multilayer ceramic electronic component 110. The first supporter 221 and the second supporter 222 in the mounted component 220 are relatively displaceable in the length direction Y (first direction). In the view of FIG. 1, the first supporter 221 and the second supporter 222 are separated from each other by space. This enables the multilayer ceramic electronic component 110 as an actuator to easily generate a relative displacement between the first supporter 221 and the second supporter 222. The space is not necessarily essential, depending on usage. The mounted component 220 may have a connected portion between the first supporter 221 and the second supporter 222.

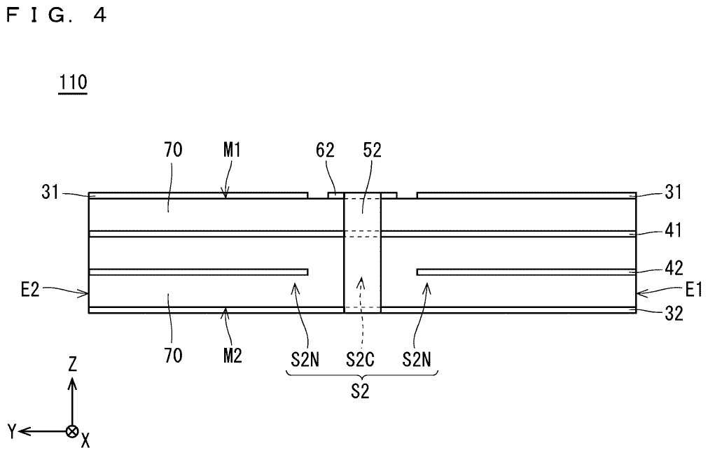

The assembly 500 further includes a first bonding portion 321, a second bonding portion 322, and a wiring part 310. The first bonding portion 321 and the second bonding portion 322 mechanically bond the multilayer ceramic electronic component 110 (specifically, a second external electrode layer 32 (FIG. 4) to be described later) to the first supporter 221 and the second supporter 222, respectively. Furthermore, at least one of the first bonding portion 321 or the second bonding portion 322 is an electrical bonding portion that electrically bonds the multilayer ceramic electronic component 110 to the mounted component 220. The electrical bonding portion is made of a material including a conductor to ensure favorable electrical conductivity. When at least one of the first bonding portion 321 or the second bonding portion 322 is an electrical bonding portion, the other need not be an electrical bonding portion, and may be made of an insulating material. Each of the first bonding portion 321 and the second bonding portion 322 is, for example, approximately 2 to 3 μm in thickness.

The assembly 500 further includes the wiring part 310 electrically bonded to the multilayer ceramic electronic component 110 (specifically, a first external electrode layer 31 (FIG. 4) to be described later). Application of an external voltage between the wiring part 310 and the aforementioned electrical bonding portion can apply a voltage to the multilayer ceramic electronic component 110. The wiring part 310 may include, for example, a wire 312 and a wire bonding portion 311.

### [Structure of Multilayer Ceramic Electronic Component]

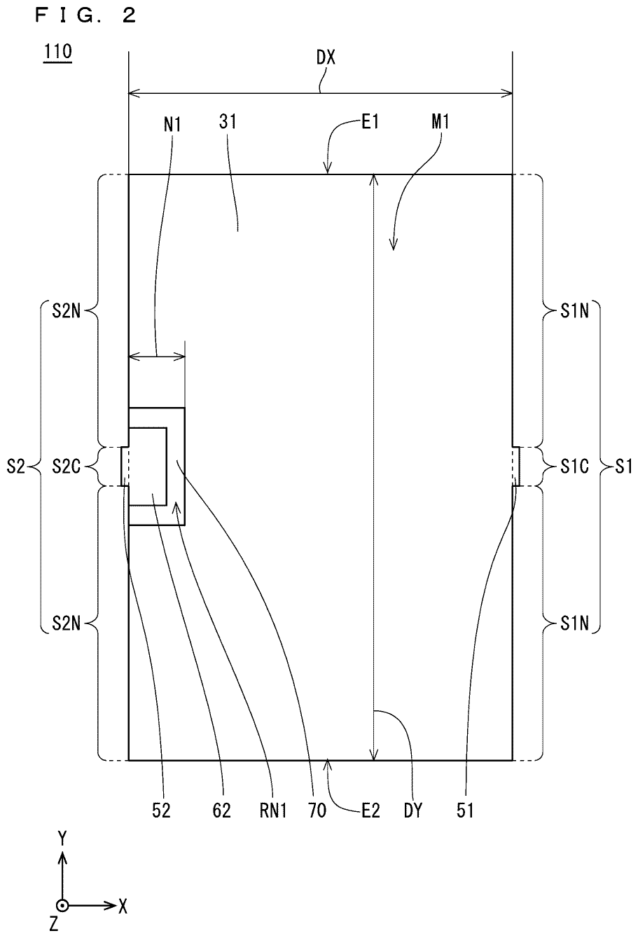

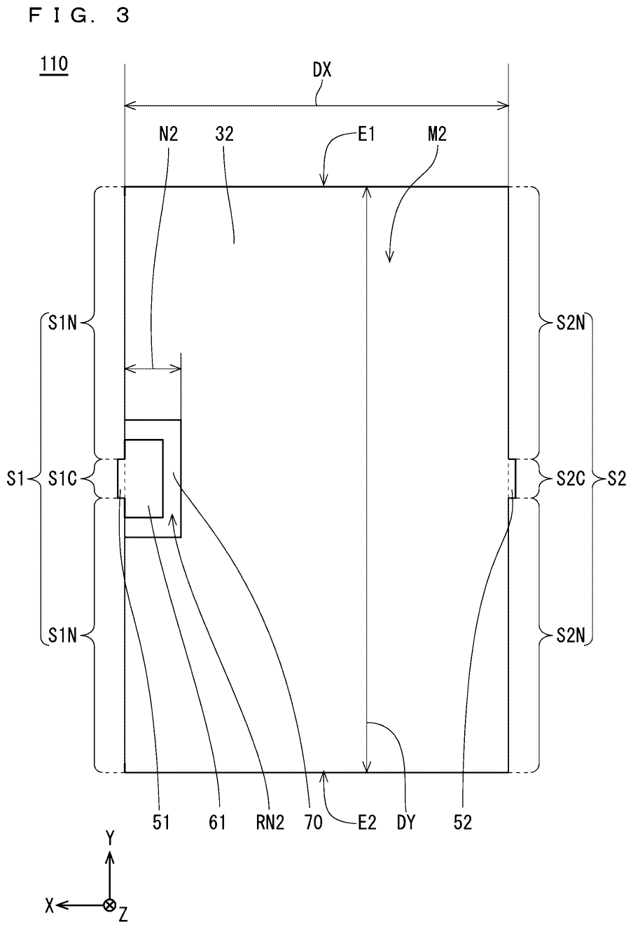

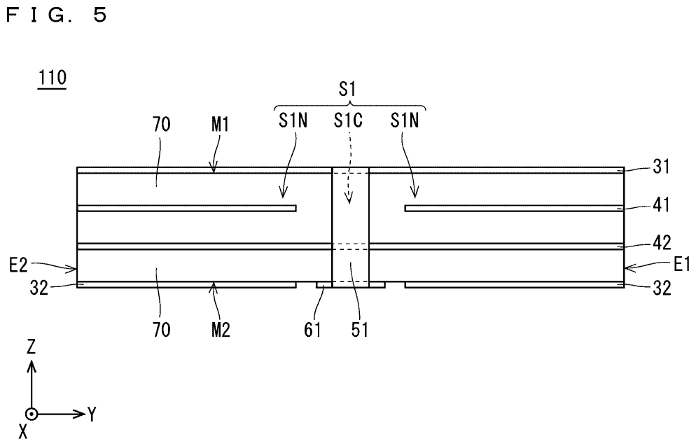

FIG. 2, FIG. 3, FIG. 4, and FIG. 5 are a top view, a bottom view, a left-side view, and a right-side view, respectively, each schematically illustrating a structure of the multilayer ceramic electronic component 110 according to Embodiment 1. The multilayer ceramic electronic component 110 includes a piezoelectric ceramic part 70, the first external electrode layer 31, the second external electrode layer 32, a first internal electrode layer 41, a second internal electrode layer 42, a first side surface electrode 51, and a second side surface electrode 52. A voltage for driving the multilayer ceramic electronic component 110 is applied between the first external electrode layer 31 and the second external electrode layer 32. Thus, the first external electrode layer 31 and the second external electrode layer 32 are electrodes having opposite polarities.

The piezoelectric ceramic part 70 has a first main surface M1 and a second main surface M2 that are opposite to each other in a thickness direction Z. The piezoelectric ceramic part 70 also has a first end surface E1 and a second end surface E2 that are opposite to each other in the length direction Y. The length direction Y is a direction different from the thickness direction Z, and is orthogonal to the thickness direction Z in Embodiment 1. The piezoelectric ceramic part 70 also has a first side surface S1 and a second side surface S2 that are opposite to each other in a width direction X (a second direction). The width direction X is a direction different from the thickness direction Z and the length direction Y, and is orthogonal to the thickness direction Z and the length direction Y in Embodiment 1.

The piezoelectric ceramic part 70 has a length dimension DY (a first dimension) and a width dimension DX (a second dimension) in the length direction Y and the width direction X, respectively. The length dimension DY may be larger than the width dimension DX, for example, 125% or more of the width dimension. The shape of the piezoelectric ceramic part 70 on an XY plane (in a plan view perpendicular to the thickness direction) is typically a rectangle with a side having a width dimension in the X direction and a side having a length dimension in the Y direction.

The first side surface S1 has first non-connection regions S1N and a first connection region SIC. The first connection region SIC connects the first main surface M1 to the second main surface M2. The second side surface S2 has second non-connection regions S2N and a second connection region S2C. The second connection region S2C connects the first main surface M1 to the second main surface M2.

The first external electrode layer 31 is disposed on the first main surface M1. The first main surface M1 includes a first inactive region RN1 that separates the first external electrode layer 31 from the second connection region S2C of the second side surface S2. Thus, the first inactive region RN1 separates the first external electrode layer 31 from the second side surface electrode 52. The second external electrode layer 32 is disposed on the second main surface M2. The second main surface M2 includes a second inactive region RN2 that separates the second external electrode layer 32 from the first connection region SIC of the first side surface S1. Thus, the second inactive region RN2 separates the second external electrode layer 32 from the first side surface electrode 51.

The first inactive region RN1 and the second inactive region RN2 have a first inactive width N1 (FIG. 2) and a second inactive width N2 (FIG. 3), respectively, in the width direction X. The piezoelectric ceramic part 70 has the width dimension DX in the width direction X. Preferably, D/N1≥2 and D/N2≥2 are satisfied, more preferably D/N1≥3 and D/N2≥3 are satisfied, and much more preferably D/N1≥4 and D/N2≥4 are satisfied.

The first internal electrode layer 41 is disposed between the first external electrode layer 31 and the second external electrode layer 32 in the piezoelectric ceramic part 70. With reference to FIG. 5, the first internal electrode layer 41 is separated from the first connection region SIC of the first side surface S1. Thus, the first internal electrode layer 41 is separated from the first side surface electrode 51. A distance between the first internal electrode layer 41 and the first side surface electrode 51 is preferably longer than or equal to 0.05 mm and shorter than or equal to 0.25 mm. When the distance is longer than or equal to 0.05 mm, the insulation distance is sufficiently ensured. When the distance is shorter than or equal to 0.25 mm, an active area is sufficiently ensured, thus resulting in a large displacement. The second internal electrode layer 42 is disposed between the second external electrode layer 32 and the first internal electrode layer 41 in the piezoelectric ceramic part 70. The second internal electrode layer 42 is separated from the second connection region S2C of the second side surface S2. Thus, the second internal electrode layer 42 is separated from the second side surface electrode 52. A distance between the second internal electrode layer 42 and the second side surface electrode 52 is preferably longer than or equal to 0.05 mm and shorter than or equal to 0.25 mm. When the distance is longer than or equal to 0.05 mm, the insulation distance is sufficiently ensured. When the distance is shorter than or equal to 0.25 mm, an active area is sufficiently ensured, thus resulting in a large displacement. On the XY plane (in a plan view perpendicular to the thickness direction), the first internal electrode layer 41 and the second external electrode layer 32 may have a common shape and a common arrangement, and the second internal electrode layer 42 and the first external electrode layer 31 may have a common shape and a common arrangement. As a first modification, a plurality of first internal electrode layers 41 may be used instead of the single first internal electrode layer 41. As a second modification, a plurality of second internal electrode layers 42 may be used instead of the single second internal electrode layer 42. The first modification may be combined with the second modification. In the combined modification, the first internal electrode layers 41 and the second internal electrode layers 42 are alternately disposed in the thickness direction.

Generally, multilayer ceramic electronic components are electronic components each with a structure in which ceramic layers and electrode layers are layered in a thickness direction. In the multilayer ceramic electronic component 110, the plurality of electrode layers consists of the first external electrode layer 31, the second external electrode layer 32, the first internal electrode layer 41, and the second internal electrode layer 42. A plurality of ceramic layers disposed between the electrode layers makes up the piezoelectric ceramic part 70. Although Embodiment 1 describes a structure including two internal electrode layers of the first internal electrode layer 41 and the second internal electrode layer 42 in the piezoelectric ceramic part 70 in detail, the number of internal electrode layers is not limited to this.

The first side surface electrode 51 is disposed on the first connection region SIC of the first side surface S1, out of the first non-connection regions S1N of the first side surface S1. The first side surface electrode 51 connects the first external electrode layer 31 to the second internal electrode layer 42 on the first side surface S1. The first side surface electrode 51 reaches the second main surface M2 in FIG. 5. The first side surface electrode 51 does not always need to reach the second main surface M2. The second side surface electrode 52 is disposed on the second connection region S2C of the second side surface S2, out of the second non-connection regions S2N of the second side surface S2. The second side surface electrode 52 connects the second external electrode layer 32 to the first internal electrode layer 41 on the second side surface S2. The second side surface electrode 52 reaches the first main surface M1 in FIG. 4. The second side surface electrode 52 does not always need to reach the first main surface M1. Each of the first side surface electrode 51 and the second side surface electrode 52 preferably has a dimension ranging from 2.5% to 25% of the length dimension DY in the Y direction. When the dimension is 2.5% or larger, the reliability on a break is sufficiently ensured. When the dimension is 25% or smaller, an active area is sufficiently ensured, thus resulting in a large displacement.

In a two-dimensional layout including the X direction and the Y direction, that is, a two-dimensional layout on the XY plane, all of the following regions overlap each other in a portion: a region in which the first external electrode layer 31 and the first internal electrode layer 41 overlap each other; a region in which the first internal electrode layer 41 and the second internal electrode layer 42 overlap each other; and a region in which the second external electrode layer 32 and the second internal electrode layer 42 overlap each other, and a percentage of the portion to a region in which the piezoelectric ceramic part 70 is disposed is defined as an active area percentage. The active area percentage corresponds to a percentage of an area of the piezoelectric ceramic part 70 in which the multilayer ceramic electronic component 110 can use its piezoelectric properties. The active area percentage is 75% or higher. The active area percentage is preferably 85% or higher, is more preferably 90% or higher, and is much more preferably 95% or higher in view of enhancing the piezoelectric properties of the multilayer ceramic electronic component 110. The active area percentage is preferably 100% or less, is more preferably 95% or less, and is much more preferably 90% or less in view of, for example, manufacturability of the piezoelectric properties of the multilayer ceramic electronic component 110.

In the two-dimensional layout, the first side surface electrode 51 and the second side surface electrode 52 are preferably symmetrically disposed in the piezoelectric ceramic part 70. Specifically, the first side surface electrode 51 and the second side surface electrode 52 may have line symmetry about a reference line extending in the Y direction, in the two-dimensional layout on the XY plane. Instead of it or together with it, the first side surface electrode 51 and the second side surface electrode 52 may have point symmetry about a reference point in the two-dimensional layout on the XY plane. The two-dimensional layouts exemplified in FIGS. 2 and 3 have both line symmetry and point symmetry.

The piezoelectric ceramic part 70 may include at least one of a first dummy electrode layer 62 or a second dummy electrode layer 61. The first dummy electrode layer 62 is disposed on a part of the first inactive region RN1 on the first main surface M1. The other portion of the first inactive region RN1 on the first main surface M1 separate the first dummy electrode layer 62 from the first external electrode layer 31. Thus, the first dummy electrode layer 62 is separated from the first external electrode layer 31. A distance between the first dummy electrode layer 62 and the first external electrode layer 31 on the XY plane is preferably longer than or equal to 0.05 mm and shorter than or equal to 0.25 mm. When the distance is longer than or equal to 0.05 mm, the insulation distance is sufficiently ensured. When the distance is shorter than or equal to 0.25 mm, an active area is sufficiently ensured, thus resulting in a large displacement. The second side surface electrode 52 reaches the first dummy electrode layer 62. The second dummy electrode layer 61 is disposed on a part of the second inactive region RN2 on the second main surface M2. The other portion of the second inactive region RN2 on the second main surface M2 separate the second dummy electrode layer 61 from the second external electrode layer 32. Thus, the second dummy electrode layer 61 is separated from the second external electrode layer 32. A distance between the second dummy electrode layer 61 and the second external electrode layer 32 on the XY plane is preferably longer than or equal to 0.05 mm and shorter than or equal to 0.25 mm. When the distance is longer than or equal to 0.05 mm, the insulation distance is sufficiently ensured. When the distance is shorter than or equal to 0.25 mm, an active area is sufficiently ensured, thus resulting in a large displacement. The first side surface electrode 51 reaches the second dummy electrode layer 61.

In Embodiment 1, the first connection region SIC of the first side surface S1 is separated from the first end surface E1 and the second end surface E2. Furthermore, the second connection region S2C of the second side surface S2 is separated from the first end surface E1 and the second end surface E2. Thus, the first side surface electrode 51 and the second side surface electrode 52 are separated from the first end surface E1 and the second end surface E2.

In Embodiment 1, the first external electrode layer 31 reaches each of the first end surface E1 and the second end surface E2. In other words, the shortest distance between the first external electrode layer 31 and each of the first end surface E1 and the second end surface E2 is 0. The second external electrode layer 32 reaches each of the first end surface E1 and the second end surface E2. In other words, the shortest distance between the second external electrode layer 32 and each of the first end surface E1 and the second end surface E2 is 0. The first internal electrode layer 41 reaches each of the first end surface E1 and the second end surface E2. In other words, the shortest distance between the first internal electrode layer 41 and each of the first end surface E1 and the second end surface E2 is 0. The second internal electrode layer 42 reaches each of the first end surface E1 and the second end surface E2. In other words, the shortest distance between the second internal electrode layer 42 and each of the first end surface E1 and the second end surface E2 is 0.

In Embodiment 1, the first external electrode layer 31 reaches each of the first side surface S1 and the second side surface S2. In other words, the shortest distance between the first external electrode layer 31 and each of the first side surface S1 and the second side surface S2 is 0. The second external electrode layer 32 reaches each of the first side surface S1 and the second side surface S2. In other words, the shortest distance between the second external electrode layer 32 and each of the first side surface S1 and the second side surface S2 is 0. The first internal electrode layer 41 reaches each of the first side surface S1 and the second side surface S2. In other words, the shortest distance between the first internal electrode layer 41 and each of the first side surface S1 and the second side surface S2 is 0. The second internal electrode layer 42 reaches each of the first side surface S1 and the second side surface S2. In other words, the shortest distance between the second internal electrode layer 42 and each of the first side surface S1 and the second side surface S2 is 0.

The dimensions of the multilayer ceramic electronic component 110 will be hereinafter exemplified. A length dimension of the piezoelectric ceramic part 70 is preferably longer than or equal to 0.8 mm and shorter than or equal to 2 mm, is more preferably longer than or equal to 0.8 mm and shorter than or equal to 1.4 mm, and is much more preferably longer than or equal to 0.8 mm and shorter than or equal to 1.3 mm. A lower limit of the width dimension of the piezoelectric ceramic part 70 is preferably 0.1 mm, and is more preferably 0.2 mm. An upper limit of the width dimension of the piezoelectric ceramic part 70 is preferably 1.0 mm, and is more preferably 0.6 mm. A dimension of each of the first inactive region RN1 and the second inactive region RN2 in the length direction Y is, for example, approximately 0.3 mm. Each of the first inactive width N1 and the second inactive width N2 is preferably longer than or equal to 0.1 mm and shorter than or equal to 0.2 mm.

A thickness dimension of the piezoelectric ceramic part 70 is preferably longer than or equal to 0.03 mm and shorter than or equal to 0.15 mm. As such, the thickness dimension of the piezoelectric ceramic part 70 may be smaller than each of the length dimension and the width dimension. This is because the function of the piezoelectric ceramic part 70 required as an actuator is not on a displacement in the thickness direction Z but on a displacement in the length direction Y.

### [Method of Manufacturing Multilayer Ceramic Electronic Component]

Next, an example method of manufacturing the multilayer ceramic electronic component 110 will be hereinafter described.

A green sheet to be the plurality of ceramic layers that make up the piezoelectric ceramic part 70 is prepared. An electrode paste pattern to be the first internal electrode layer 41 and the second internal electrode layer 42 is formed on the green sheet. Next, sequentially layering the green sheets forms a laminate sheet. An electrode paste pattern is formed on the first main surface M1 of the laminate sheet. This electrode paste pattern is to be the first external electrode layer 31 and the first dummy electrode layer 62. Furthermore, an electrode paste pattern is formed on the second main surface M2 of the laminate sheet. This electrode paste pattern is to be the second external electrode layer 32 and the second dummy electrode layer 61.

Next, cutting the laminate sheet forms the first side surface S1 and the second side surface S2. Then, electrode paste portions corresponding to the first side surface electrode 51 and the second side surface electrode 52 are formed. Specifically, a viscous electrode paste is applied by screen printing so that a process of washing the electrode paste away from on the first dummy electrode layer 62 on the first inactive region RN1 of the first main surface M1 onto the second connection region S2C of the second side surface S2, and a process of washing the electrode paste away from on the second dummy electrode layer 61 on the second inactive region RN2 of the second main surface M2 onto the first connection region SIC of the first side surface S1 are performed.

Next, cutting the laminate sheet forms the first end surface E1 and the second end surface E2. This cutting forms, from the laminate sheet, green chips corresponding to the respective multilayer ceramic electronic components 110. Next, these green chips are fired. Then, each of the chips is subjected to a polarization treatment. These produce the multilayer ceramic electronic components 110. Although application of an electrode paste, which can be generally implemented at low cost, is described above as a method for forming electrodes, the method for forming electrodes is not limited to this. For example, sputtering may be used.

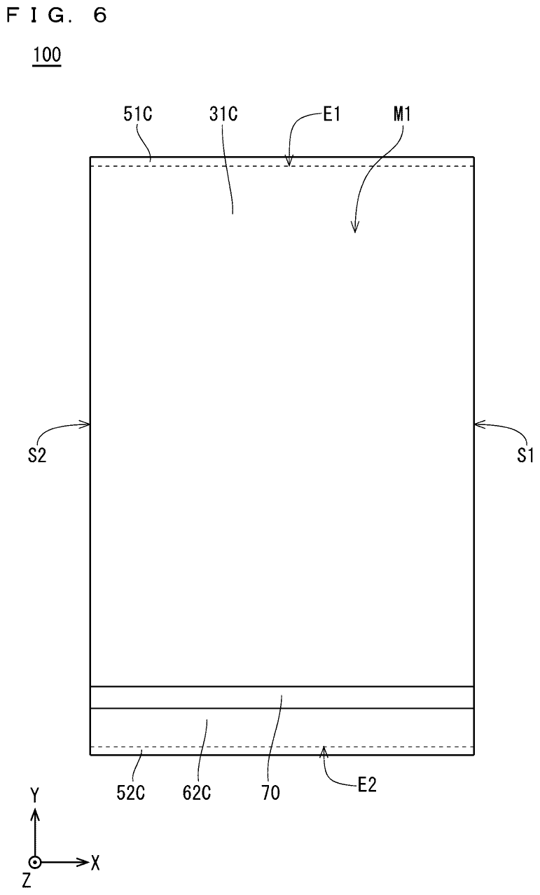

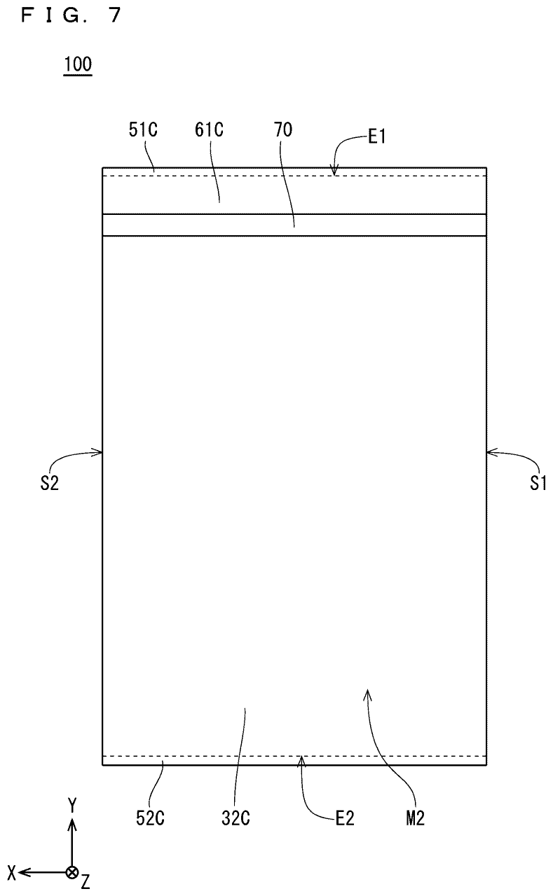

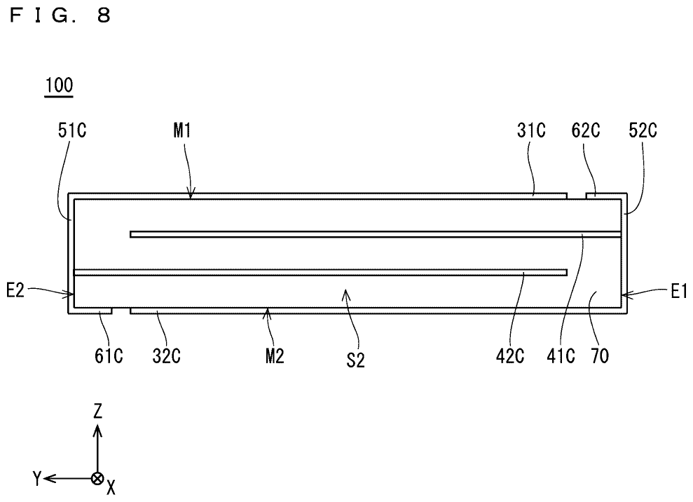

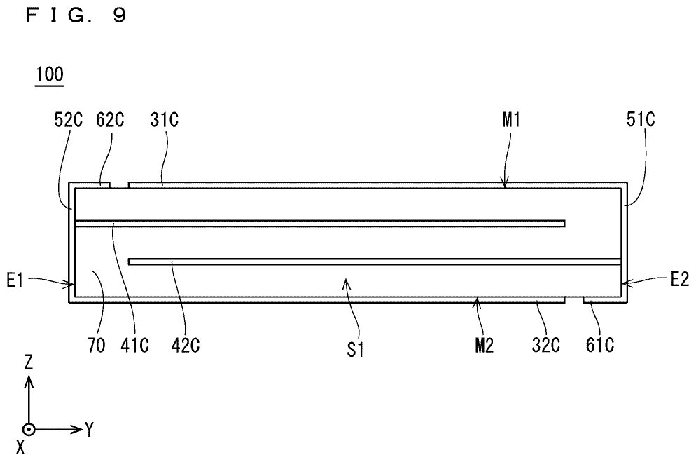

FIG. 6, FIG. 7, FIG. 8, and FIG. 9 are a top view, a bottom view, a left-side view, and a right-side view, respectively, each schematically illustrating a structure of a multilayer ceramic electronic component 100 of a comparative example. The multilayer ceramic electronic component 100 (FIGS. 6 to 9) includes a first external electrode layer 31C, a second external electrode layer 32C, a first internal electrode layer 41C, a second internal electrode layer 42C, a first side surface electrode 51C, a second side surface electrode 52C, a second dummy electrode layer 61C, and a first dummy electrode layer 62C, instead of the first external electrode layer 31, the second external electrode layer 32, the first internal electrode layer 41, the second internal electrode layer 42, the first side surface electrode 51, the second side surface electrode 52, the second dummy electrode layer 61, and the first dummy electrode layer 62 in the multilayer ceramic electronic component 110 (FIGS. 2 to 5).

The first external electrode layer 31C and the second external electrode layer 32C are disposed on the first main surface M1 and the second main surface M2, respectively. The first external electrode layer 31C reaches the first end surface E1, and is separated from the second end surface E2. The second external electrode layer 32C is separated from the first end surface E1, and reaches the second end surface E2. On the XY plane (in a plan view perpendicular to the thickness direction), the first internal electrode layer 41C and the second external electrode layer 32C have a common shape and a common arrangement, and the second internal electrode layer 42C and the first external electrode layer 31C have a common shape and a common arrangement. The first side surface electrode 51C and the second side surface electrode 52C are disposed on the first end surface E1 and the second end surface E2, respectively. The first side surface electrode 51C is in contact with the first external electrode layer 31C and the second internal electrode layer 42C. The second side surface electrode 52C is in contact with the second external electrode layer 32C and the first internal electrode layer 41C. The first dummy electrode layer 62C is disposed on a part of the first main surface M1, and is separated from the first external electrode layer 31C. The second side surface electrode 52C directly reaches the first dummy electrode layer 62C. The second dummy electrode layer 61C is disposed on a part of the second main surface M2, and is separated from the second external electrode layer 32C. The first side surface electrode 51C directly reaches the second dummy electrode layer 61C.

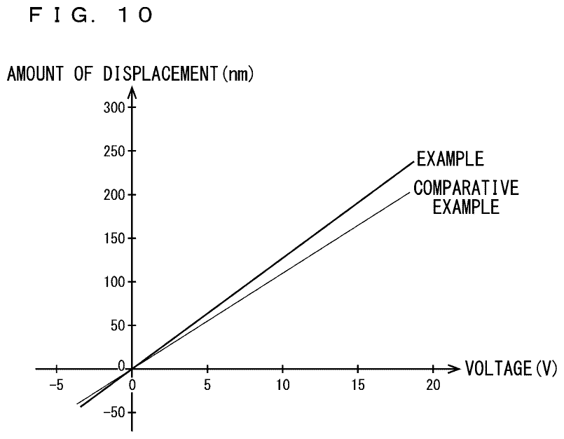

FIG. 10 is a graph illustrating an example simulation result on a relationship between a voltage and the amount of displacement in Example of Embodiment 1 (see FIG. 2) and a comparative example (see FIG. 6). The piezoelectric ceramic part 70 has a dimension of 1.1 mm in the length direction Y, a dimension of 0.74 mm in the width direction X, a dimension of 0.048 mm in the thickness direction Z, and includes three ceramic layers as the simulation conditions. The simulation method is piezoelectric harmonic analysis using software “Femtet” (trademark) developed by Murata Software Co., Ltd. The simulation result is that, for example, the amount of displacement at a voltage of 18.5 V is 242 nm in Example, and is 191 nm in the comparative example.

Table 1 below indicates the simulation result on a relationship between an active area percentage and the amount of displacement.

TABLE 1

| | Arrangement | | | | | | | |
|---|---|---|---|---|---|---|---|---|
| | of side | Element | Element | Inactive | Inactive | Active | Amount of | |
| | surface | length | width | width | length | area | displacement | |
| | electrodes | [mm] | [mm] | [mm] | [mm] | percentage | [nm] | Evaluation |
| Example 1 | Long side | 1.2 | 0.5 | 0.15 | 0.3 | 85% | 273 | A |
| Example 2 | Long side | 1.2 | 0.5 | 0.15 | 0.5 | 75% | 255 | B |
| Example 3 | Long side | 1.2 | 0.3 | 0.15 | 0.3 | 75% | 250 | B |
| Example 4 | Long side | 1.2 | 0.4 | 0.15 | 0.3 | 81% | 264 | B |
| Comparative | Short side | 1.2 | 0.5 | 0.5 | 0.1 | 83% | 248 | F |
| example 1 | | | | | | | | |
| Comparative | Long side | 1.2 | 0.4 | 0.15 | 0.5 | 69% | 237 | F |
| example 2 | | | | | | | | |
| Comparative | Long side | 1.2 | 0.3 | 0.15 | 0.5 | 58% | 215 | F |
| example 3 | | | | | | | | |

In the column of “Arrangement of side surface electrodes” in Table 1, “Long side” means that the multilayer ceramic electronic component 110 (FIGS. 2 to 5) with an arrangement of side surface electrodes such as the first side surface electrode 51 and the second side surface electrode 52 is used as a model, and “Short side” means that the multilayer ceramic electronic component 100 (FIGS. 6 to 9) with an arrangement of side surface electrodes such as the first side surface electrode 51C and the second side surface electrode 52C is used as a model. The dimensions are those indicated by Table 1. Furthermore, the columns of “Element length” and “Element width” indicate the length and the width, respectively, of each of the models. The column of “Inactive width” corresponds to each of the first inactive width N1 and the second inactive width N2 when the “Long side” models are used, and corresponds to the element width when the “Short side” model is used. The column of “Inactive length” corresponds to the length of each of the first inactive region RN1 and the second inactive region RN2 when the “Long side” models are used, and corresponds to the length of an exposed portion (a dimension in the Y direction) of the piezoelectric ceramic part 70 in each of FIGS. 6 and 7 when the “Short side” model is used. In the column of “Evaluation”, when the amount of displacement in the comparative example 1 is defined as 100%, “A” corresponds to 110% or higher, “B” corresponds to more than 100% and less than 110%, and “F” corresponds to 100% or lower.

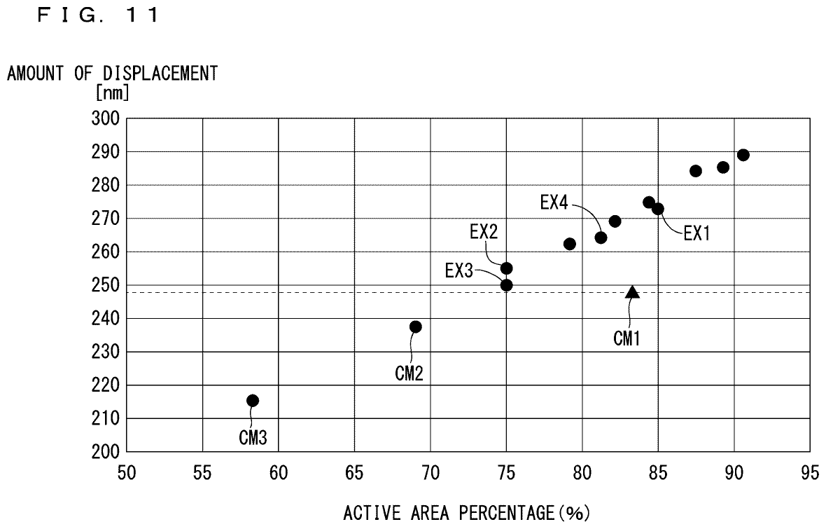

FIG. 11 is a graph illustrating an example simulation result on a relationship between an active area percentage and the amount of displacement. In FIG. 11, circular marks correspond to the “Long side” models (see FIGS. 2 to 5), and a triangular mark corresponds to the “Short side” model (FIGS. 6 to 9). With also reference to Table 1, a comparative example CM1 corresponds to the comparative example 1, a comparative example CM2 and a comparative example CM3 correspond to the comparative example 2 and the comparative example 3, respectively, and Examples EX1 to EX4 correspond to Embodiments 1 to 4, respectively. The broken line in FIG. 11 indicates the amount of displacement of the comparative example CM1. Thus, the circular marks above the broken line correspond to the models each of which can generate an amount of displacement larger than that of the typical “Short side” model, among the “Long side” models. This result indicates that the “Long side” models with the active area percentages higher than or equal to 75% with respect to that of the typical “Short side” model can generate larger amounts of displacement, and the “Long side” models with the active area percentages higher than or equal to 85% can generate significantly larger amounts of displacement.

### Advantages

The multilayer ceramic electronic component 110 (FIGS. 2 to 5) according to Embodiment 1 can generate a larger amount of displacement.

The multilayer ceramic electronic component 110 is an actuator for generating a displacement in the length direction Y. Consequently, the amount of displacement that can be generated by the multilayer ceramic electronic component 110 can be used as the amount of displacement of an actuator.

The mounted component 220 included in the assembly 500 (FIG. 1) includes the first supporter 221 and the second supporter 222 that support the multilayer ceramic electronic component 110. The first supporter 221 and the second supporter 222 in the mounted component 220 are relatively displaceable in the length direction Y. Consequently, the multilayer ceramic electronic component 110 can control a dimension between the first supporter 221 and the second supporter 222 in the mounted component 220.

The first connection region SIC of the first side surface S1 is separated from the first end surface E1 and the second end surface E2, and the second connection region S2C of the second side surface S2 is separated from the first end surface E1 and the second end surface E2. Thus, the first side surface electrode 51 and the second side surface electrode 52 can be disposed away from the first end surface E1 and the second end surface E2. Each of the first external electrode layer 31, the second external electrode layer 32, the first internal electrode layer 41, and the second internal electrode layer 42 reaches the first end surface E1 and the second end surface E2. This can significantly increase the dimension of an active portion in the length direction Y as a displacement direction.

Each of the first external electrode layer 31, the second external electrode layer 32, the first internal electrode layer 41, and the second internal electrode layer 42 reaches the first side surface S1 and the second side surface S2. This can significantly reduce a degree in which the displacement of an active portion of the piezoelectric ceramic part 70 is inhibited by an inactive portion of the piezoelectric ceramic part 70.

### Embodiment 2

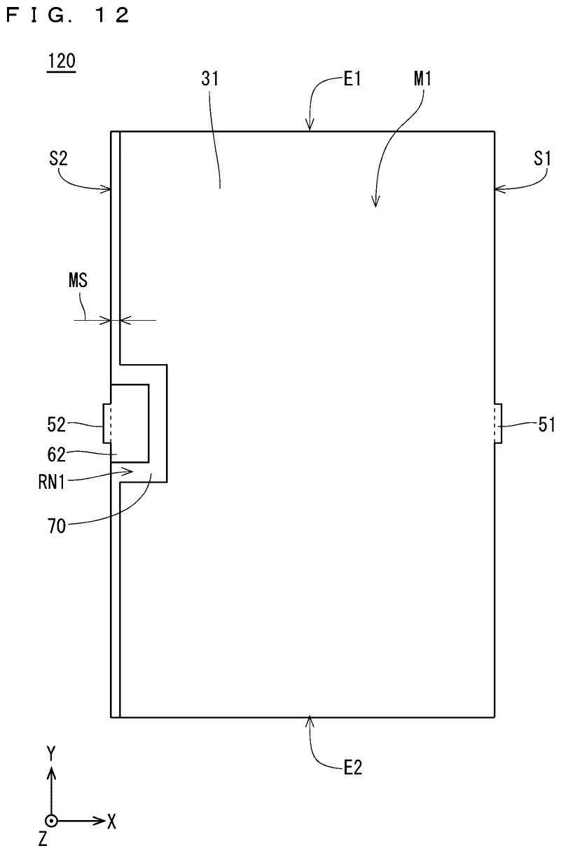

FIG. 12 is a top view schematically illustrating a structure of a multilayer ceramic electronic component 120 according to Embodiment 2. The multilayer ceramic electronic component 120 (FIG. 12) differs from the multilayer ceramic electronic component 110 (FIG. 2) in that the shortest distance MS between the first external electrode layer 31 and the second side surface S2 is larger than 0. Here, the shortest distance MS is 10 μm or less. Although the illustration is omitted, similarly, the shortest distance between the second external electrode layer 32 and the first side surface S1 is more than 0 and 10 μm or less, a distance between the first internal electrode layer 41 and the first side surface S1 is more than 0 and 10 μm or less, and a distance between the second internal electrode layer 42 and the second side surface S2 is more than 0 and 10 μm or less. Preferably, the shortest distance MS is 5 μm or less, the shortest distance between the second external electrode layer 32 and the first side surface S1 is 5 μm or less, the distance between the first internal electrode layer 41 and the first side surface S1 is 5 μm or less, and the distance between the second internal electrode layer 42 and the second side surface S2 is 5 μm or less.

The piezoelectric ceramic part 70 according to Embodiment 2 covers the first internal electrode layer 41 on the first side surface S1. This prevents the first internal electrode layer 41 from having unintended current leakage on the first side surface S1. Similarly, the piezoelectric ceramic part 70 covers the second internal electrode layer 42 on the second side surface S2. This prevents the second internal electrode layer 42 from having unintended current leakage on the second side surface S2. If the shortest distance MS is excessively long, the degree in which the displacement of the active portion of the piezoelectric ceramic part 70 is inhibited by the inactive portion of the piezoelectric ceramic part 70 also becomes excessively high. Since the shortest distance MS is 10 μm or less in Embodiment 2, such a detrimental effect can be suppressed.

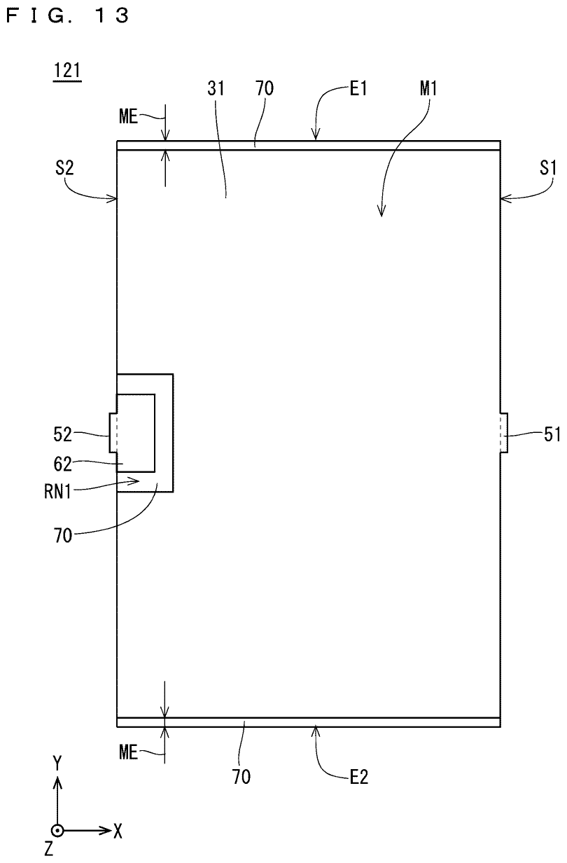

FIG. 13 is a top view schematically illustrating a structure of a multilayer ceramic electronic component 121 according to a first modification of Embodiment 2. The multilayer ceramic electronic component 121 (FIG. 13) differs from the multilayer ceramic electronic component 110 (FIG. 2) in that the shortest distance ME between the first external electrode layer 31 and each of the first end surface E1 and the second end surface E2 is larger than 0. Here, the shortest distance ME is 10 μm or less. Although the illustration is omitted, similarly, the shortest distance between the second external electrode layer 32 and each of the first end surface E1 and the second end surface E2 is more than 0 and 10 μm or less, the shortest distance between the first internal electrode layer 41 and each of the first end surface E1 and the second end surface E2 is more than 0 and 10 μm or less, and the shortest distance between the second internal electrode layer 42 and each of the first end surface E1 and the second end surface E2 is more than 0 and 10 μm or less. Preferably, the shortest distance ME is 5 μm or less, the shortest distance between the second external electrode layer 32 and each of the first end surface E1 and the second end surface E2 is 5 μm or less, the shortest distance between the first internal electrode layer 41 and each of the first end surface E1 and the second end surface E2 is 5 μm or less, and the shortest distance between the second internal electrode layer 42 and each of the first end surface E1 and the second end surface E2 is 5 μm or less.

In this modification, the piezoelectric ceramic part 70 covers the first internal electrode layer 41 and the second internal electrode layer 42 on the first end surface E1 and the second end surface E2. This prevents the first internal electrode layer 41 and the second internal electrode layer 42 from having unintended current leakage on the first end surface E1 and the second end surface E2. If the shortest distance ME is excessively long, the dimension of the active portion in the length direction Y as a displacement direction is excessively sacrificed. Since the shortest distance ME is 10 μm or less in Embodiment 2, such a detrimental effect can be suppressed.

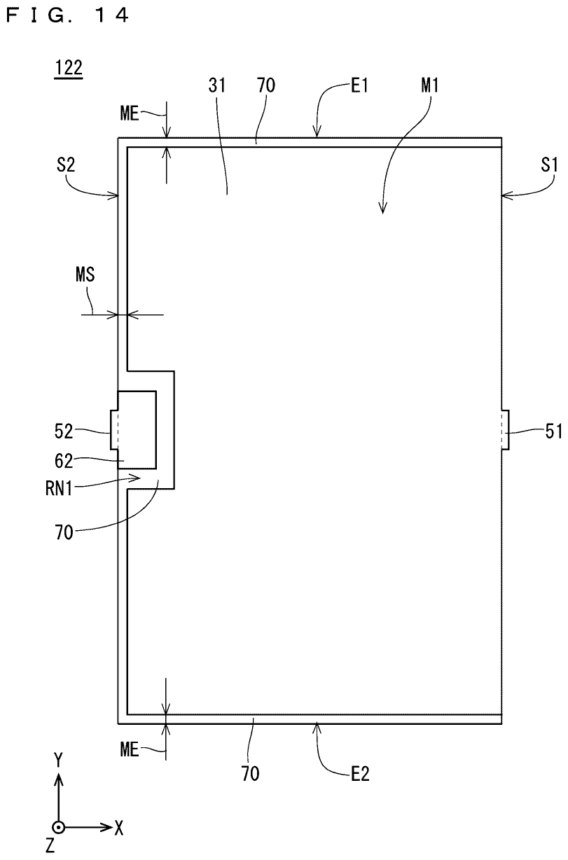

FIG. 14 is a top view schematically illustrating a structure of a multilayer ceramic electronic component 122 according to a second modification of Embodiment 2. This modification has characteristics of both of Embodiment 2 and the first modification.

### Embodiment 3

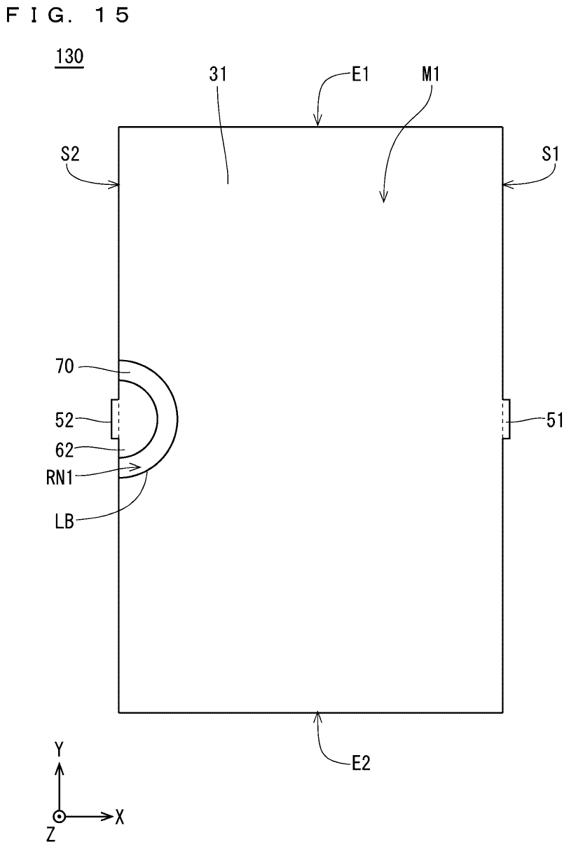

FIG. 15 is a top view schematically illustrating a structure of a multilayer ceramic electronic component 130 according to Embodiment 3. The first inactive region RN1 is in contact with the first external electrode layer 31 along a first boundary LB in a plan view. The first boundary LB does not include a straight portion orthogonal to the length direction Y. The first boundary LB consists of a curve in Embodiment 2. Preferably, the same holds true for a second boundary. This curve is an arc with a central angle of 180 degrees, that is, a semi-circle in the example of FIG. 15. As a modification, the central angle of the arc may be an angle different from 180 degrees. Preferably, the central angle is less than 180 degrees in such a case. As another modification, an elliptical arc may be used instead of the arc.

The second inactive region RN2 is in contact with the second external electrode layer 32 along the second boundary (not illustrated). Preferably, the second boundary also has characteristics of the first boundary LB. A structure in which the first boundary LB does not have the characteristics but the second boundary has the characteristics may be used.

Since the structures other than the described structure are the same as those according to Embodiment 1, Embodiment 2, or the modifications, the same reference numerals are attached to the same or corresponding elements and the description thereof is not repeated.

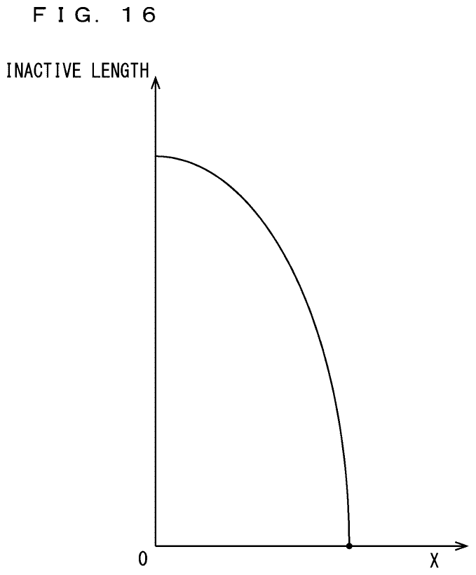

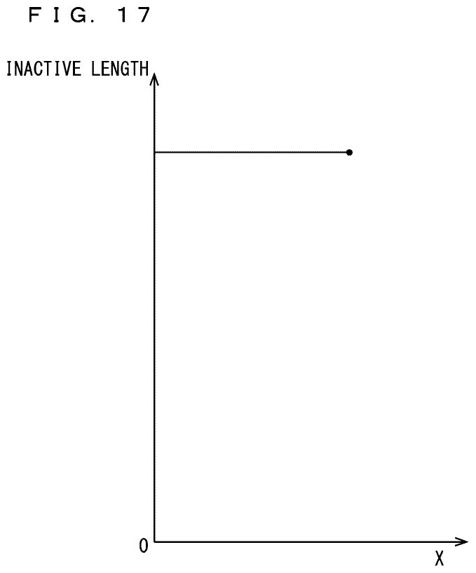

FIG. 16 and FIG. 17 are graphs illustrating a distribution of an inactive length (the dimension of the first inactive region RN1 in the Y direction) in the multilayer ceramic electronic component 130 (FIG. 15: Embodiment 3) and a distribution of an inactive length in the multilayer ceramic electronic component 110 (FIG. 2: Embodiment 1), respectively. In the graphs, the position X=0 corresponds to the second side surface S2, and the position of the point corresponds to the deepest position of the first inactive region RN1 in the width direction X on the first main surface M1. Embodiment 3 differs from Embodiment 1 in that the inactive length decreases with distance from the second side surface S2. This decrease is continuous. Furthermore, Embodiment 3 differs from Embodiment 1 in that the inactive length converges to zero at the deepest position of the first inactive region RN1 (the position of the point in FIG. 16).

In Embodiment 3, stress concentrations near the first boundary LB can be mitigated.

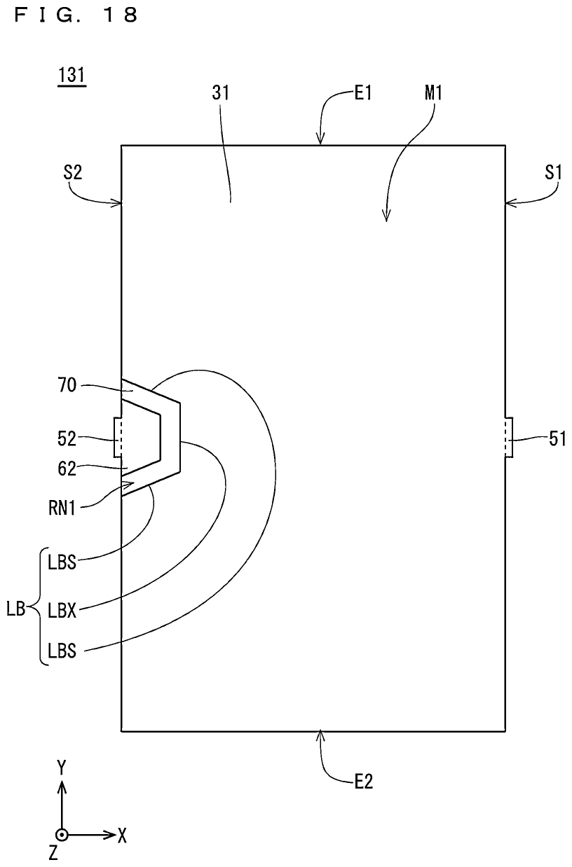

FIG. 18 is a top view schematically illustrating a structure of a multilayer ceramic electronic component 131 according to a first modification of Embodiment 3. The first boundary LB includes a straight portion LBX and straight portions LBS. The straight portions LBS are inclined in each of the length direction Y and the width direction X (a direction orthogonal to the length direction Y). The straight portion LBX is along the length direction Y. In the example illustrated in FIG. 18, the shape enclosed by the second side surface S2 and the first boundary LB is a trapezoid. Preferably, the second boundary also has the same characteristics. A structure in which the first boundary LB does not have the characteristics but the second boundary has the characteristics may be used. When the area of the first inactive region RN1 (and the second inactive region RN2) may be small, the shape of the first inactive region RN1 (and the second inactive region RN2) may be not a trapezoid but a triangle by omitting the straight portion LBX along the direction Y.

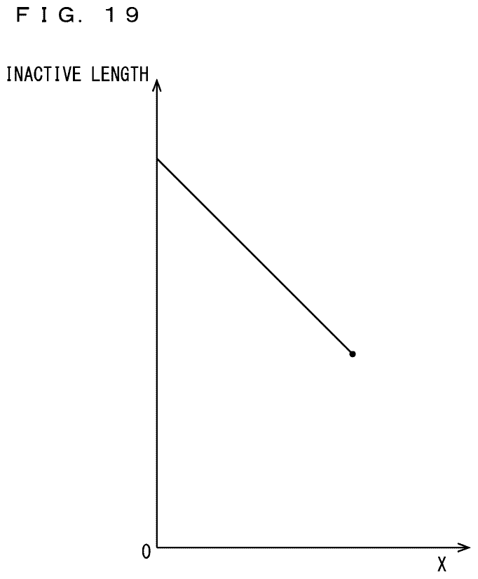

FIG. 19 is a graph illustrating a distribution of an inactive length in the multilayer ceramic electronic component 131 of FIG. 18. In the graph, the position X=0 corresponds to the second side surface S2, and the position of the point corresponds to the deepest position of the first inactive region RN1 in the width direction X on the first main surface M1. This first modification differs from Embodiment 1 in that the inactive length decreases with distance from the second side surface. This decrease is continuous.

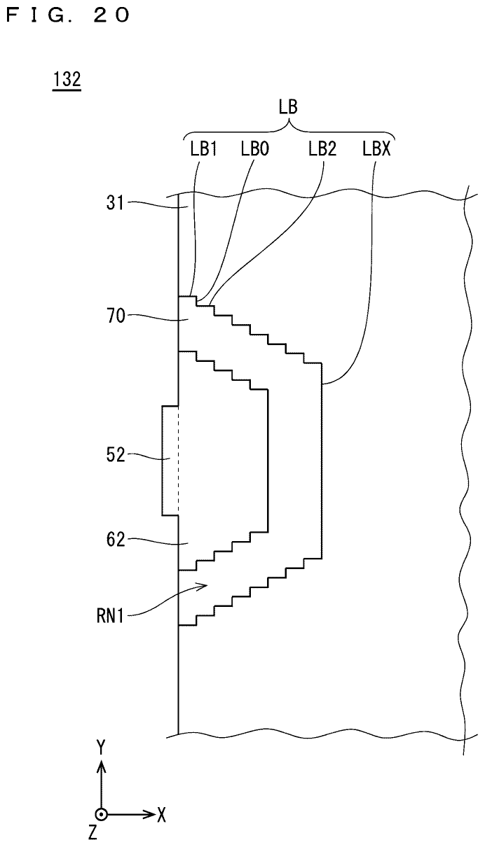

FIG. 20 is a top view schematically illustrating a structure of a multilayer ceramic electronic component 132 according to a second modification of Embodiment 3. The first boundary LB includes a first straight portion LB1, a second straight portion LB2, and an intermediate portion LB0 in a plan view. The first straight portion LB1 is orthogonal to the length direction Y. The second straight portion LB2 is orthogonal to the length direction Y, and is separated from the first straight portion LB1. The intermediate portion LB0 has a first end connected to the first straight portion LB1 and a second end connected to the second straight portion LB2, and does not include a straight portion orthogonal to the length direction Y. In FIG. 20, a direction of the first straight portion LB1 extending from the first end of the intermediate portion LB0 is a left direction, and a direction of the second straight portion LB2 extending from the second end of the intermediate portion LB0 is a right direction. Thus, the direction of the first straight portion LB1 extending from the first end of the intermediate portion LB0 is opposite to the direction of the second straight portion LB2 extending from the second end of the intermediate portion LB0.

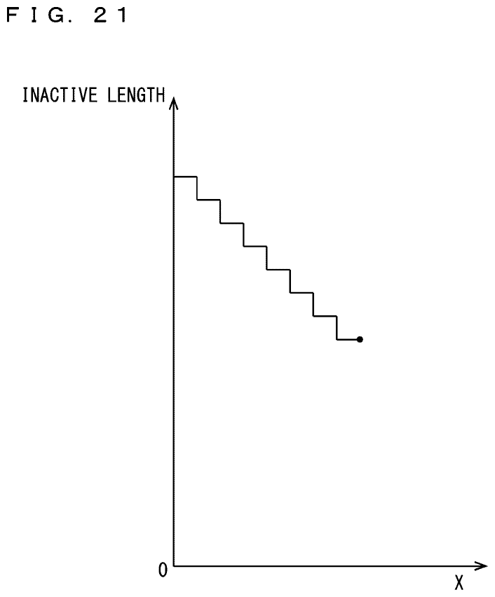

FIG. 21 is a graph illustrating a distribution of an inactive length in the multilayer ceramic electronic component 132 of FIG. 20. In the graph, the position X=0 corresponds to the second side surface S2, and the position of the point corresponds to the deepest position of the first inactive region RN1 in the width direction X on the first main surface M1. This second modification differs from Embodiment 1 in that the inactive length decreases with distance from the second side surface. This decrease is discontinuous.

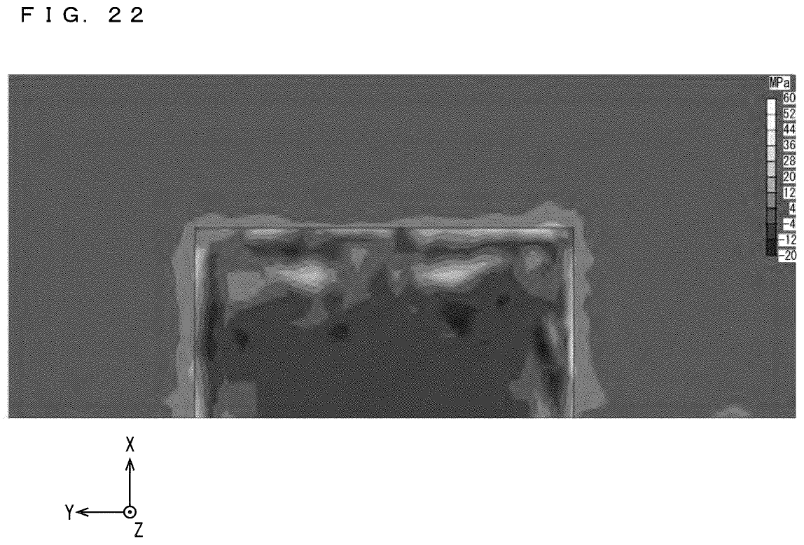

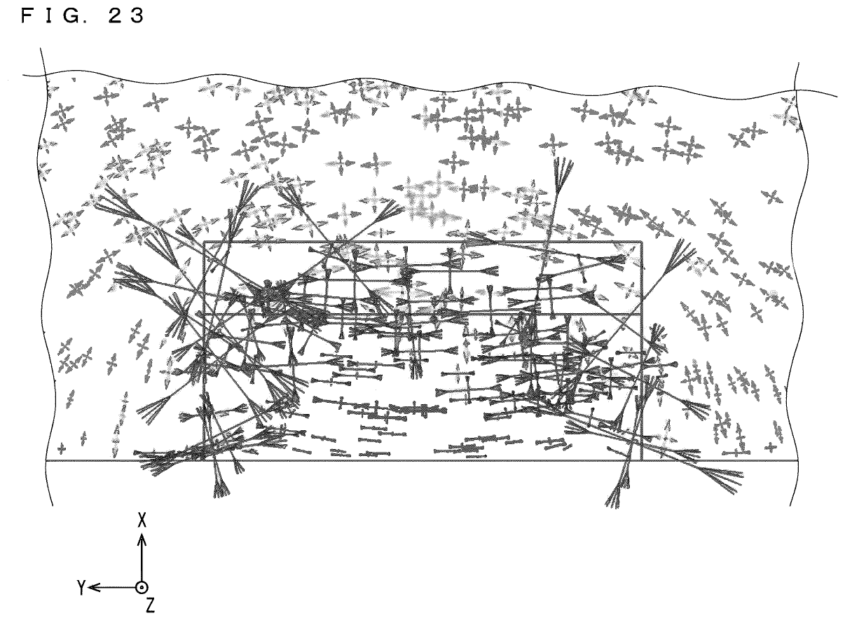

FIG. 22 and FIG. 23 are a contour map and a vector diagram, respectively, each illustrating an example simulation result on a stress distribution near an inactive region in the multilayer ceramic electronic component 110 (FIG. 2) under a piezoelectric displacement. The piezoelectric ceramic part 70 has a dimension of 1.1 mm in the length direction Y, a dimension of 0.74 mm in the width direction X, a dimension of 0.048 mm in the thickness direction Z, and includes three ceramic layers as the simulation conditions. The simulation method is the piezoelectric harmonic analysis using the software “Femtet” (trademark) developed by Murata Software Co., Ltd. In FIG. 22, a positive value corresponds to a tensile stress, and a negative value corresponds to a compressive stress. In the drawings, a rectangle indicated by black lines corresponds to the first inactive region RN1. In this simulation, the maximum stress of 55 MPa is generated near the center of the right short side of the rectangle.

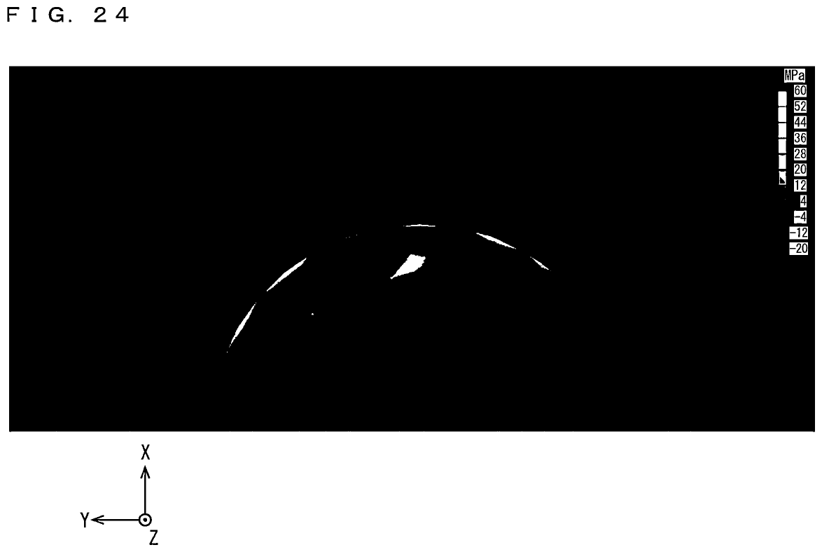

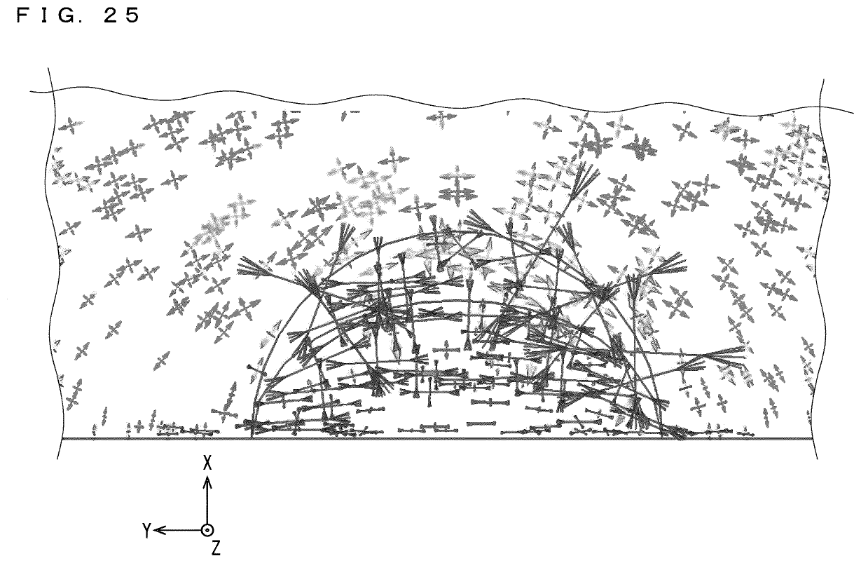

FIG. 24 and FIG. 25 are a contour map and a vector diagram, respectively, each illustrating an example simulation result on a stress distribution near an inactive region in the multilayer ceramic electronic component 130 (FIG. 15) under a piezoelectric displacement. The simulation method in FIG. 24 and FIG. 25 is identical to that of FIG. 22 and FIG. 23. The simulation conditions in FIG. 24 and FIG. 25 differ from those of FIG. 22 and FIG. 23 by a condition on a pattern of the electrode layers as illustrated in the drawings. However, the other conditions are the same. In FIG. 24, a positive value corresponds to a tensile stress, and a negative value corresponds to a compressive stress. In the drawings, a semi-circle indicated by a black line corresponds to the first inactive region RN1. In this simulation, the maximum stress of 45 MPa is generated near the left center of the arc.

According to the two simulation results, the maximum stress in the multilayer ceramic electronic component 110 (FIG. 2) is 55 MPa, and the maximum stress in the multilayer ceramic electronic component 130 (FIG. 15) is 45 MPa. This clarifies that the maximum stress of the latter can be reduced more than that of the former under a piezoelectric displacement.

Embodiments and its modifications may be freely combined. Although this invention has been described in detail, the description is in all aspects illustrative and does not restrict the invention. It is therefore understood that numerous modifications and variations that have not yet been exemplified can be devised without departing from the scope of the invention.

What is claimed is:

1. A multilayer ceramic electronic component, comprising
a piezoelectric ceramic part including:
a first main surface and a second main surface that are opposite to each other in a thickness direction;
a first end surface and a second end surface that are opposite to each other in a first direction different from the thickness direction;
a first side surface and a second side surface that are opposite to each other in a second direction different from the thickness direction and the first direction; and
a first dimension in the first direction and a second dimension in the second direction, the first dimension being larger than the second dimension,
the multilayer ceramic electronic component further comprising:
a first external electrode layer disposed on the first main surface;
a second external electrode layer disposed on the second main surface;
a first internal electrode layer disposed between the first external electrode layer and the second external electrode layer in the piezoelectric ceramic part;
a second internal electrode layer disposed between the second external electrode layer and the first internal electrode layer in the piezoelectric ceramic part;
a first side surface electrode that connects the first external electrode layer to the second internal electrode layer on the first side surface, the first side surface electrode being separated from the first internal electrode layer; and
a second side surface electrode that connects the second external electrode layer to the first internal electrode layer on the second side surface, the second side surface electrode being separated from the second internal electrode layer,
wherein in a two-dimensional layout including the first direction and the second direction, all of the following regions overlap each other in a portion higher than or equal to 75% of a region in which the piezoelectric ceramic part is disposed:
a region in which the first external electrode layer and the first internal electrode layer overlap each other;
a region in which the first internal electrode layer and the second internal electrode layer overlap each other; and
a region in which the second external electrode layer and the second internal electrode layer overlap each other.

2. The multilayer ceramic electronic component according to claim 1,
wherein the percentage is higher than or equal to 85%.

3. The multilayer ceramic electronic component according to claim 1,
wherein each of the first side surface electrode and the second side surface electrode has a dimension larger than or equal to 2.5% and smaller than or equal to 25% of the first dimension in the first direction.

4. The multilayer ceramic electronic component according to claim 1,
wherein in the two-dimensional layout, the first side surface electrode and the second side surface electrode are symmetrically disposed in the piezoelectric ceramic part.

5. The multilayer ceramic electronic component according to claim 1,
wherein each of the first side surface electrode and the second side surface electrode is separated from the first end surface and the second end surface.

6. The multilayer ceramic electronic component according to claim 1,
wherein a shortest distance between the first external electrode layer and each of the first end surface and the second end surface is 0 or more and 10 μm or less, a shortest distance between the second external electrode layer and each of the first end surface and the second end surface is 0 or more and 10 μm or less, a shortest distance between the first internal electrode layer and each of the first end surface and the second end surface is 0 or more and 10 μm or less, and a shortest distance between the second internal electrode layer and each of the first end surface and the second end surface is 0 or more and 10 μm or less.

7. The multilayer ceramic electronic component according to claim 1,
wherein the first external electrode layer reaches each of the first end surface and the second end surface, the second external electrode layer reaches each of the first end surface and the second end surface, the first internal electrode layer reaches each of the first end surface and the second end surface, and the second internal electrode layer reaches each of the first end surface and the second end surface.

8. The multilayer ceramic electronic component according to claim 1,
wherein a shortest distance between the first external electrode layer and the second side surface is 0 or more and 10 μm or less, a shortest distance between the second external electrode layer and the first side surface is 0 or more and 10 μm or less, a distance between the second internal electrode layer and the second side surface is 0 or more and 10 μm or less, and a distance between the first internal electrode layer and the first side surface is 0 or more and 10 μm or less.

9. The multilayer ceramic electronic component according to claim 1,
wherein the first external electrode layer reaches each of the first side surface and the second side surface, the second external electrode layer reaches each of the first side surface and the second side surface, the first internal electrode layer reaches each of the first side surface and the second side surface, and the second internal electrode layer reaches each of the first side surface and the second side surface.

10. The multilayer ceramic electronic component according to claim 1,
wherein the first main surface includes a first inactive region that separates the first external electrode layer from the second side surface electrode, and the second main surface includes a second inactive region that separates the second external electrode layer from the first side surface electrode.

11. The multilayer ceramic electronic component according to claim 10,
the multilayer ceramic electronic component further comprising:
a first dummy electrode layer disposed on the first inactive region of the first main surface and separated from the first external electrode layer; and/or
a second dummy electrode layer disposed on the second inactive region of the second main surface and separated from the second external electrode layer.

12. The multilayer ceramic electronic component according to claim 10,
wherein in a plan view, the first inactive region is in contact with the first external electrode layer along a first boundary, the second inactive region is in contact with the second external electrode layer along a second boundary, and at least one of the first boundary or the second boundary does not include a straight portion orthogonal to the first direction.

13. The multilayer ceramic electronic component according to claim 12,
wherein at least one of the first boundary or the second boundary consists of a curve.

14. The multilayer ceramic electronic component according to claim 12,
wherein at least one of the first boundary or the second boundary includes a straight portion inclined in each of the first direction and a direction orthogonal to the first direction.

15. The multilayer ceramic electronic component according to claim 10,
wherein in a plan view, the first inactive region is in contact with the first external electrode layer along a first boundary, the second inactive region is in contact with the second external electrode layer along a second boundary, and at least one of the first boundary or the second boundary includes:
a first straight portion orthogonal to the first direction;
a second straight portion orthogonal to the first direction and separated from the first straight portion; and
an intermediate portion which has a first end connected to the first straight portion and a second end connected to the second straight portion, and which does not include a straight portion orthogonal to the first direction, and
a direction of the first straight portion extending from the first end of the intermediate portion is opposite to a direction of the second straight portion extending from the second end of the intermediate portion.

16. The multilayer ceramic electronic component according to claim 1,
wherein the first side surface has a first non-connection region and a first connection region,
the first side surface electrode is disposed on the first connection region of the first side surface, out of the first non-connection region of the first side surface, and
the first non-connection region has, in the first side surface, a part separating the first internal electrode layer from the first side surface electrode.

17. The multilayer ceramic electronic component according to claim 1,
wherein the multilayer ceramic electronic component is an actuator for generating a displacement in the first direction.

18. An assembly, comprising:
the multilayer ceramic electronic component according to claim 1; and
a mounted component on which the multilayer ceramic electronic component is mounted,
wherein the mounted component includes a first supporter and a second supporter that support the multilayer ceramic electronic component, and the first supporter and the second supporter in the mounted component are relatively displaceable in the first direction.
